(19) United States
(12) Patent Application Publication
(10) Pub. No.: US 2014/0225121 A1
(43) Pub. Date: Aug. 14, 2014

(54) AlGaN TEMPLATE FABRICATION METHOD AND STRUCTURE OF THE AlGaN TEMPLATE

(71) Applicant: Electronics and Telecommunications Research Institute, Daejeon (KR)

(72) Inventors: Sung-Bum BAE, Daejeon (KR); Sung Bock KIM, Daejeon (KR); Eun Soo NAM, Daejeon (KR)

(73) Assignee: Electronics and Telecommunications Research Institute, Daejeon (KR)

(21) Appl. No.: 14/143,716

(22) Filed: Dec. 30, 2013

(30) Foreign Application Priority Data
Feb. 13, 2013 (KR) 10-2013-0015412

(51) Int. Cl. H01L 21/02; H01L 29/20

(52) U.S. Cl. CPC H01L 21/0254; H01L 29/2003
USPC 257/76; 438/478

(57) ABSTRACT

Provided are an aluminum gallium nitride template and a fabrication method thereof. The fabrication method includes forming an aluminum nitride (AlN) layer on a substrate, forming a first aluminum gallium nitride (AlₓGa₁₋ₓN) layer on the aluminum nitride (AlN) layer, forming a second aluminum gallium nitride (Al_{y}Ga_{1-y}N) layer on the first aluminum gallium nitride (AlₓGa₁₋ₓN) layer, forming a third aluminum gallium nitride (Al_{z}Ga_{1-z}N) layer on the second aluminum gallium nitride (Al_{y}Ga_{l-y}N) layer, wherein the first aluminum gallium nitride (AlₓGa₁₋ₓN) layer, the second aluminum gallium nitride (Al_{y}Ga_{1-y}N) layer, and the third aluminum gallium nitride (Al_{z}Ga_{1-z}N) layer are formed to have crystal defects and a composition ratio of aluminum (where 1>x>y>z>0) that are gradually decreased as heights of the layers are increased.

### CROSS-REFERENCE TO RELATED APPLICATIONS

This U.S. non-provisional patent application claims priority under 35 U.S.C. §119 of Korean Patent Application No. 10-2013-0015412, filed on Feb. 13, 2013, the entire contents of which are hereby incorporated by reference.

### BACKGROUND

The present invention disclosed herein relates to templates and fabricating methods thereof, and more particularly, to AlGaN templates and fabricating methods thereof.

Gallium nitride (GaN)-based compound semiconductors, as direct transition type semiconductors, may be possible to control wavelength from visible light to ultraviolet light and may have excellent physical properties, such as high thermal and chemical stability, high electron mobility and saturation electron velocity, and a large energy bandgap, in comparison to typical gallium arsenide (GaAs) and indium phosphide (InP)-based compound semiconductors. Based on these properties, the application of the GaN-based compound semiconductors have expanded to areas in which typical compound semiconductors have limitations, for example, an optical device, such as a visible light-emitting diode (LED) and a laser diode (LD), or electronic devices used in advanced wireless communication and satellite communication systems that require high-power and high-frequency characteristics. In particular, an ultraviolet light-emitting device is a safe and eco-friendly light source that may address limitations of a typical ultraviolet light source (e.g., metal halide mercury lamp). Also, the ultraviolet light-emitting device may be used in various application areas, such as a light source for lighting and environmental and medical light sources for sterilization and disinfection, according to a wavelength range of ultraviolet light, and is in the early stage of commercialization.

A GaN (3.4 eV, 364 nm) layer having short wavelength characteristics, an aluminum nitride (A1N, 6.2 eV, 200 nm) layer, and an aluminum gallium nitride (AlGaN) layer, which is a ternary semiconductor according to a composition ratio of aluminum (Al), are mainly used in order to fabricate an ultraviolet light-emitting device by using a nitride semiconductor. For example, a composition ratio of AlGaN of an active layer which controls an emission wavelength may increase as the wavelength decreases, and an AlGaN layer having a higher composition ratio than the active layer may be used in order to prevent light absorption even in an n-type or p-type electrode layer. Therefore, the biggest technical issue for the commercialization of an ultraviolet light-emitting diode is to secure an epitaxial growth technique for high quality and low defect AlGaN having a high compositional ratio of Al, and research into various epitaxial structures and growth techniques has been conducted in order to address the above issue.

### SUMMARY

The present invention provides an aluminum gallium nitride template that may minimize crystal defects and a fabrication method thereof.

Embodiments of the inventive concepts provide methods of fabricating an aluminum gallium nitride template including: forming an aluminum nitride (AlN) layer on a substrate; forming a first aluminum gallium nitride (AlₓGa₁₋ₓN) layer on the aluminum nitride (AlN) layer; forming a second aluminum gallium nitride (Al_{y}Ga_{1-y}N) layer on the first aluminum gallium nitride (AlₓGa₁₋ₓN) layer; and forming a third aluminum gallium nitride (Al_{z}Ga_{1-z}N) layer on the second aluminum gallium nitride (Al_{y}Ga_{1-y}N) layer, wherein the first aluminum gallium nitride (AlₓGa₁₋ₓN) layer, the second aluminum gallium nitride (Al_{y}Ga_{1-y}N) layer, and the third aluminum gallium nitride (Al_{z}Ga_{1-z}N) layer may have crystal defects and a composition ratio of aluminum (where 1>x>y>z>0) that are gradually decreased as heights of the the first aluminum gallium nitride (AlₓGa₁₋ₓN) layer, the second aluminum gallium nitride (Al_{y}Ga_{1-y}N) layer, and the third aluminum gallium nitride (Al_{z}Ga_{1-z}N) layer are increased.

In some embodiments, the forming of the aluminum nitride (AlN) layer may include: forming a flat aluminum nitride (AlN) layer on the substrate; and forming an embossed aluminum nitride (AlN) layer on the flat aluminum nitride layer.

In other embodiments, the embossed aluminum nitride (AlN) layer may be formed of convex structures of a tetrahedral crystal structure.

In still other embodiments, the crystal defects may be bent at an interface between the embossed aluminum nitride (AlN) layer and the first aluminum gallium nitride (AlₓGa₁₋ₓN) layer in directions of edges of the convex structures.

In even other embodiments, the embossed aluminum nitride (AlN) layer may has smaller crystal defects than the flat aluminum nitride (AlN) layer.

In yet other embodiments, the first aluminum gallium nitride (AlₓGa₁₋ₓN) layer, the second aluminum gallium nitride (Al_{y}Ga_{1-y}N) layer, and the third aluminum gallium nitride (Al_{z}Ga_{1-z}N) layer may be formed to be gradually flat on the embossed aluminum nitride (AlN) layer.

In further embodiments, the flat aluminum nitride (AlN) layer, the embossed aluminum nitride layer, the first aluminum gallium nitride (AlₓGa₁₋ₓN) layer, the second aluminum gallium nitride (Al_{y}Ga_{1-y}N) layer, and the third aluminum gallium nitride (Al_{z}Ga_{1-z}N) layer may be formed by a metal organic chemical vapor deposition method.

In still further embodiments, the flat aluminum nitride layer and the embossed aluminum nitride layer may use trimethyl aluminum gas and ammonia gas as source gases of the metal organic chemical vapor deposition method.

In even further embodiments, the flat aluminum nitride layer may be formed from 120μ mol of the trimethyl aluminum gas and 5 liters of the ammonia gas.

In yet further embodiments, the embossed aluminum nitride layer may be formed from 120μ mol of the trimethyl aluminum gas and 10 liters of the ammonia gas.

In much further embodiments, the first aluminum gallium nitride (AlₓGa₁₋ₓN) layer, the second aluminum gallium nitride (Al_{y}Ga_{1-y}N) layer, and the third aluminum gallium nitride (Al_{z}Ga_{1-z}N) layer may use the trimethyl aluminum gas, trimethyl gallium gas, and the ammonia gas as source gases of the metal organic chemical vapor deposition method

In still much further embodiments, the first aluminum gallium nitride (AlₓGa₁₋ₓN) layer may be formed from 120μ mol of the trimethyl aluminum gas, 60μ mol of the trimethyl gallium gas, and 5 liters of the ammonia gas.

In even much further embodiments, the second aluminum gallium nitride (Al_{y}Ga_{1-y}N) layer may be formed from 120μ mol of the trimethyl aluminum gas, 90μ mol of the trimethyl gallium gas, and 5 liters of the ammonia gas.

In yet much further embodiments, the third aluminum gallium nitride (Al_{z}Ga_{1-z}N) layer may be formed from 120μ mol of the trimethyl aluminum gas, 120μ mol of the trimethyl gallium gas, and 5 liters of the ammonia gas.

In other embodiment of the inventive concepts, aluminum gallium nitride templates include: a substrate; an aluminum nitride layer on the substrate; and an aluminum gallium nitride layer covering the aluminum nitride layer and having smaller crystal defects than the aluminum nitride layer.

In some embodiments, the aluminum nitride layer may include a flat aluminum nitride layer; and an embossed aluminum nitride layer that includes convex structures protruding from the flat aluminum nitride layer.

In other embodiments, the convex structures of the embossed aluminum nitride layer may have a tetrahedral crystal structure.

In still other embodiments, the crystal defects may be bent at an interface between the flat aluminum nitride layer and the embossed aluminum nitride layer in directions of edges of the convex structures.

In even other embodiments, the crystal defects may be again bent at an interface between the embossed aluminum nitride layer and the aluminum gallium nitride layer in the directions of the edges of the convex structures.

In yet other embodiments, the aluminum gallium nitride layer may include: a first aluminum gallium nitride (AlₓGa₁₋ₓN) layer on the embossed aluminum nitride layer; a second aluminum gallium nitride (Al_{y}Ga_{1-y}N) layer covering the first aluminum gallium nitride (AlₓGa₁₋ₓN) layer and having a higher composition ratio of aluminum than the first aluminum gallium nitride layer (AlₓGa₁₋ₓN); and a third aluminum gallium nitride (Al_{z}Ga_{1-z}N) layer covering the second aluminum gallium nitride (Al_{y}Ga_{1-y}N) layer and having a higher composition ratio of aluminum than the second aluminum gallium nitride (Al_{y}Ga_{1-y}N) layer.

### BRIEF DESCRIPTION OF THE DRAWINGS

The accompanying drawings are included to provide a further understanding of the present invention, and are incorporated in and constitute a part of this specification. The drawings illustrate exemplary embodiments of the inventive concepts and, together with the description, serve to explain principles of the present invention. In the drawings:

FIG. 1 is a cross-sectional view illustrating an aluminum gallium nitride template according to an embodiment of the inventive concepts;

FIG. 2 is an enlarged view of FIG. 1;

FIG. 3 illustrates metal organic chemical vapor deposition equipment for fabricating the aluminum gallium nitride template of FIG. 1; and

FIGS. 4 through 8 are cross-sectional views illustrating a method of fabricating an aluminum gallium nitride template according to an embodiment of the inventive concepts based on FIG. 1.

### DETAILED DESCRIPTION OF THE EMBODIMENTS

Hereinafter, preferred embodiments of the inventive concepts will be described with reference to the accompanying drawings to fully explain the present invention in such a manner that it may easily be carried out by a person with ordinary skill in the art to which the present invention pertains. The present invention may, however, be embodied in different forms and should not be construed as limited to the embodiments set forth herein.

In the drawings, parts not related to descriptions are omitted for clarity, and like reference numerals denote like elements throughout the specification.

When it is described that one “comprises” some elements, it should be understood that it may comprise only those elements, or it may comprise other elements as well as those elements if there is no specific limitation.

It will be understood that when an element such as a layer, film, region, or substrate is referred to as being “on” another element, it can be directly on the other element or intervening elements may also be present therebetween. In contrast, when an element is referred to as being “directly on” another element, there are no intervening elements present.

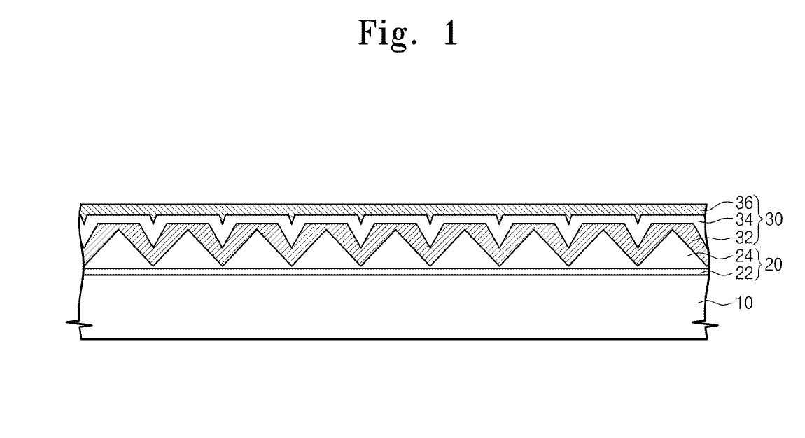

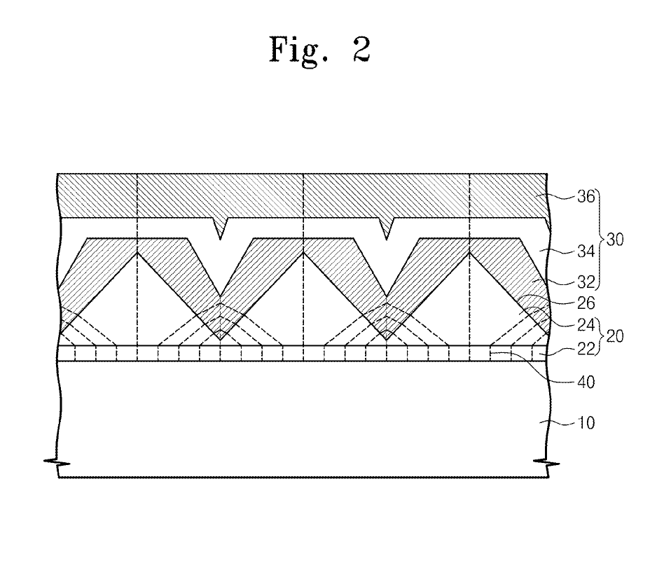

FIG. 1 is a cross-sectional view illustrating an aluminum gallium nitride template according to an embodiment of the inventive concepts. FIG. 2 is an enlarged view of FIG. 1.

Referring to FIGS. 1 and 2, the aluminum gallium nitride template according to the embodiment of the inventive concepts may include a substrate 10, an aluminum nitride layer 20, and an aluminum gallium nitride layer 30. The substrate 10 may include a sapphire or silicon substrate.

The aluminum nitride (AlN) layer 20 may include a flat aluminum nitride layer 22 and an embossed aluminum nitride layer 24. The flat aluminum nitride layer 22 may have a thickness of about 10 nm to about 50 nm. The flat aluminum nitride layer 22 may have crystal defects 40 in a direction perpendicular to the substrate 10. The crystal defects 40 may be generated due to lattice mismatch between the substrate 10 and the aluminum nitride layer 20. For example, a silicon (111) substrate, as a substrate of a group 4 element, may have a cubic structure with covalent bonding. The flat aluminum nitride layer 22 may have a hexagonal wurzite structure with covalent bonding or ionic bonding.

The embossed aluminum nitride layer 24 may have convex structures 26. The convex structures 26 may have a tetrahedral crystal structure. The crystal defects 40 may be bent at an interface between the embossed aluminum nitride layer 24 and the flat aluminum nitride layer 22. The convex structures 26 may be continuously connected on the flat aluminum nitride layer 22. The crystal defects 40 may be bent in directions of edges of the convex structures 40. The crystal defects 40 of the flat aluminum nitride layer 22 may be again bent from an upper surface of the embossed aluminum nitride layer 24. The embossed aluminum nitride layer 24 may have a thickness of about 10 nm to about 200 nm.

The aluminum gallium nitride (AlGaN) layer 30 may provide a flat upper surface by burying the convex structures 26 of the embossed aluminum nitride layer 24. The aluminum gallium nitride (AlGaN) layer 30 may include a first aluminum gallium nitride (AlₓGa₁₋ₓN) layer 32, a second aluminum gallium nitride (Al_{y}Ga_{1-y}N) layer 34, and a third aluminum gallium nitride (Al_{z}Ga_{1-z}N) layer 36. The first aluminum gallium nitride (AlₓGa₁₋ₓN) layer 32, the second aluminum gallium nitride (Al_{y}Ga_{1-y}N) layer 34, and the third aluminum gallium nitride (Al_{z}Ga_{1-z}N) layer 36 may have a composition ratio (where 1>x>y>z>0), in which an amount of aluminum is gradually decreased as heights of the aluminum gallium nitride (AlGaN) layer 30 are increased.

The first aluminum gallium nitride layer 32 may have smaller crystal defects than the aluminum nitride layer 20. The crystal defects 40 may be bent between the embossed aluminum nitride layer 24 and the first aluminum gallium nitride layer 32. The crystal defects 40 may be removed by converging in a direction of a valley between the convex structures. The first aluminum gallium nitride layer 32 may have a thickness of about 10 nm to about 300 nm.

The second aluminum gallium nitride layer 34 may have smaller crystal defects than the first aluminum gallium nitride layer 32. The crystal defects 40 may be almost removed from the first aluminum gallium nitride layer 32 and the second aluminum gallium nitride layer 34. Also, the second aluminum gallium nitride layer 34 may have a lower amount of aluminum than the first aluminum gallium nitride layer 32. In contrast, the second aluminum gallium nitride layer 34 may have a greater amount of gallium than the first aluminum gallium nitride layer 32. The second aluminum gallium nitride layer 34 may have a thickness of about 10 nm to about 300 nm.

The third aluminum gallium nitride layer 36 may provide a flat surface by removing valleys of the second aluminum gallium nitride layer 34. The third aluminum gallium nitride layer 36 may have a lower amount of aluminum than the second aluminum gallium nitride layer 34. In contrast, the third aluminum gallium nitride layer 36 may have a greater amount of gallium than the second aluminum gallium nitride layer 34. The third aluminum gallium nitride layer 36 may have a thickness of about 10 nm to about 300 nm. The crystal defects 40 may almost not appear on the flat surface of the third aluminum gallium nitride layer 36.

Therefore, the aluminum gallium nitride template according to the embodiment of the inventive concepts may have minimized crystal defects or cracks.

The aluminum nitride (AlN) layer 20 and the aluminum gallium nitride (AlGaN) layer 30 may be formed by using metal organic chemical vapor deposition equipment. However, the present invention is not limited thereto, and the aluminum nitride (AlN) layer 20 and the aluminum gallium nitride (AlGaN) layer 30 may be formed by using molecular beam epitaxy (MBE) equipment.

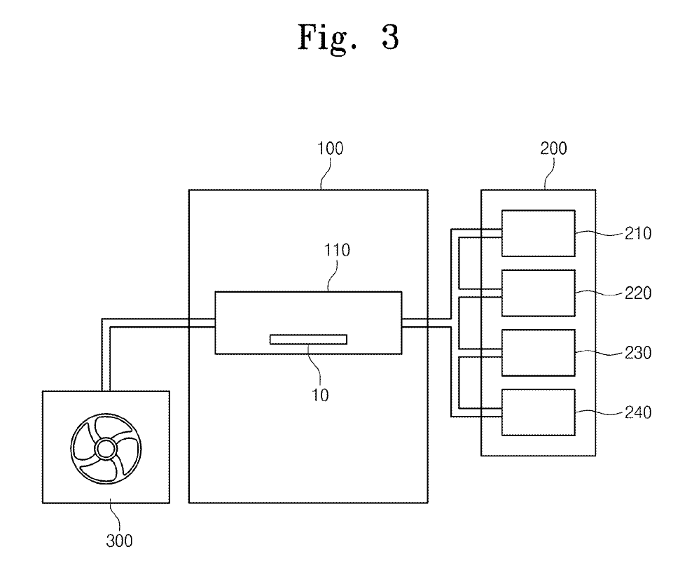

FIG. 3 illustrates metal organic chemical vapor deposition equipment for fabricating the aluminum gallium nitride template of FIG. 1.

Referring to FIGS. 1 and 3, the metal organic chemical vapor deposition equipment may include a reactor 100, a gas supply unit 200, and a vacuum pump 300. The reactor 100 may accommodate and heat a substrate 10. The vacuum pump 300 may pump out air in the reactor 100. The gas supply unit 200 may provide various reaction gases into the reactor 100. The reaction gases may include trimethyl aluminum gas, trimethyl gallium gas, and ammonia gas. For example, the gas supply unit 200 may include a trimethyl aluminum gas supply part 210, a trimethyl gallium gas supply part 220, an ammonia gas supply part 230, and a purge gas supply part 240. The trimethyl aluminum gas and the ammonia gas are source gases of the aluminum nitride layer 20. The trimethyl aluminum gas, the trimethyl gallium gas, and the ammonia gas are source gases of the aluminum gallium nitride layer 30. The metal organic chemical vapor deposition equipment may form the aluminum nitride layer 20 and the aluminum gallium nitride layer 30 in situ on the substrate 10.

Hereinafter, a method of fabricating an aluminum gallium nitride template using metal organic chemical vapor deposition equipment will be described below.

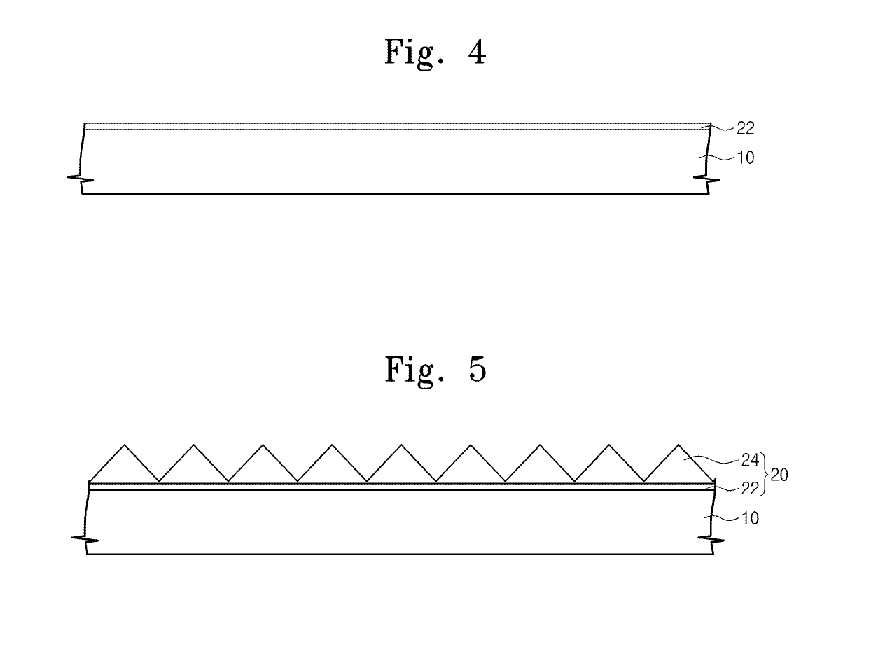

FIGS. 4 through 8 are cross-sectional views illustrating a method of fabricating an aluminum gallium nitride template according to an embodiment of the inventive concepts based on FIG. 1.

Referring to FIGS. 2 to 4, a flat aluminum nitride layer 22 is formed on a substrate 10. The flat aluminum nitride layer 22 may be formed from trimethyl aluminum gas and ammonia gas. For example, the gas supply unit 200 may provide about 120μ mol of the trimethyl aluminum gas and about 5 liters of the ammonia gas per minute into the reactor 100. The reactor 100 may form the flat aluminum nitride layer 22 at a high temperature of about 500° C. or more. The flat aluminum nitride layer 22 may be formed to have a thickness of about 50 nm for about 40 minutes. In this case, the crystal defects 40 in the flat aluminum nitride layer 22 may progress in a direction perpendicular to the substrate 10.

Referring to FIGS. 2 to 5, an embossed aluminum nitride layer 24 is formed on the flat aluminum nitride layer 22. The embossed aluminum nitride layer 24 may be formed from trimethyl aluminum gas and ammonia gas. The gas supply unit 200 may provide about 120μ mol of the trimethyl aluminum gas and about 2.5 liters of the ammonia gas per minute. A deposition rate of the embossed aluminum nitride layer 24 may increase as a flow rate of the ammonia gas decreases when a flow rate of the trimethyl aluminum gas is constant. The embossed aluminum nitride layer 24 may be deposited at a faster rate than the flat aluminum nitride layer 22. The embossed aluminum nitride layer 24 may be grown while the deposition rate in a direction of a diagonal of the substrate 10 is decreased. Therefore, the embossed aluminum nitride layer 24 may have a lower quality than the flat aluminum nitride layer 22. That is, the embossed aluminum nitride layer 24 may have a rough surface. The embossed aluminum nitride layer 24 may be formed of the convex structures 26. The convex structures 26 may have a tetrahedral crystal structure. The crystal defects 40 may be bent at an interface between the convex structures 26 and the flat aluminum nitride layer 22. The convex structures 26 may allow the crystal defects 40 to progress in directions of edges thereunder. The crystal defects 40 may extend in a direction of a valley of the convex structures 26. Therefore, the convex structures 26 may change a moving direction of the crystal defects 40.

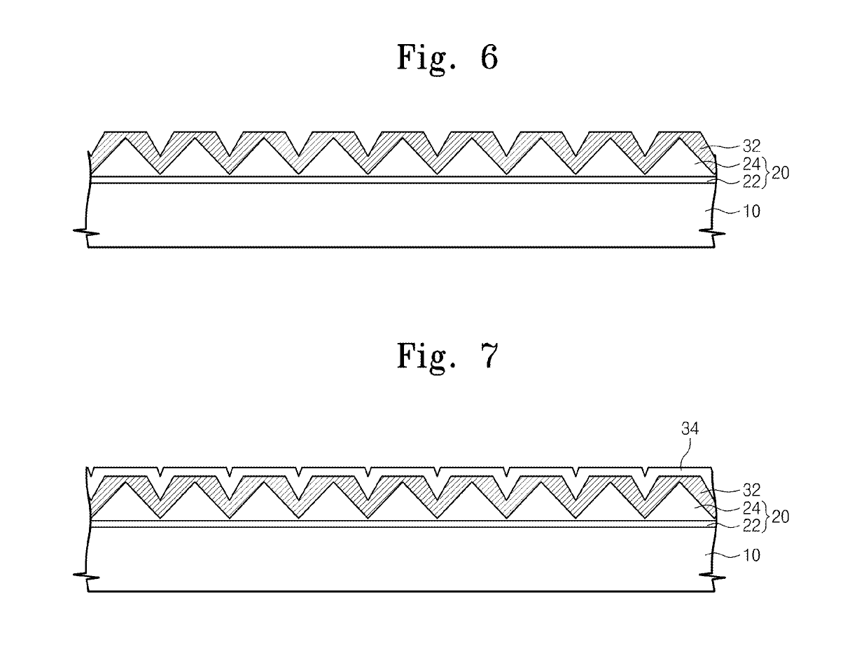

Referring to FIGS. 3 and 6, a first aluminum gallium nitride layer 32 is formed on the embossed aluminum nitride layer 24. The first aluminum gallium nitride layer 32 may be formed from trimethyl aluminum gas, trimethyl gallium gas, and ammonia gas. The gas supply unit 200 may provide about 120μ mol of the trimethyl aluminum gas, about 60μ mol of the trimethyl gallium gas, and about 5 liters of the ammonia gas per minute into the reactor 100. The first aluminum gallium nitride layer 32 may be formed to have a thickness of about 10 nm to about 300 nm. A component ratio of gallium to aluminum of the first aluminum gallium nitride layer 32 may be about 0.5:0.5. The crystal defects 40 may be again bent at an interface between the flat aluminum nitride layer 22 and the fist aluminum nitride layer 32. The crystal defects 40 may be intensively formed at the valleys or inclined surfaces of the convex structures 26 of the first aluminum gallium nitride layer 32. Most of the crystal defects 40 may be removed at valleys of the first aluminum gallium nitride layer 32.

Referring to FIGS. 3 and 7, a second aluminum gallium nitride layer 34 is formed on the first aluminum gallium nitride layer 32. The gas supply unit 200 may provide about 120μ mol of trimethyl aluminum gas, about 60μ mol of trimethyl gallium gas, and about 5 liters of ammonia gas per minute into the reactor 100. The second aluminum gallium nitride layer 34 may include a lower amount of aluminum than the first aluminum gallium nitride layer 32. A content ratio of gallium to aluminum in the second aluminum gallium nitride layer 34 may be increased as the flow rate of the trimethyl gallium gas increases. Also, the second aluminum gallium nitride layer 34 may have smaller crystal defects than the first aluminum gallium nitride layer 32. Although not shown in FIGS. 3 and 7, the crystal defects 40 may be made to progress in a nearly horizontal direction even if the crystal defects 40 remain in the second aluminum gallium nitride layer 34.

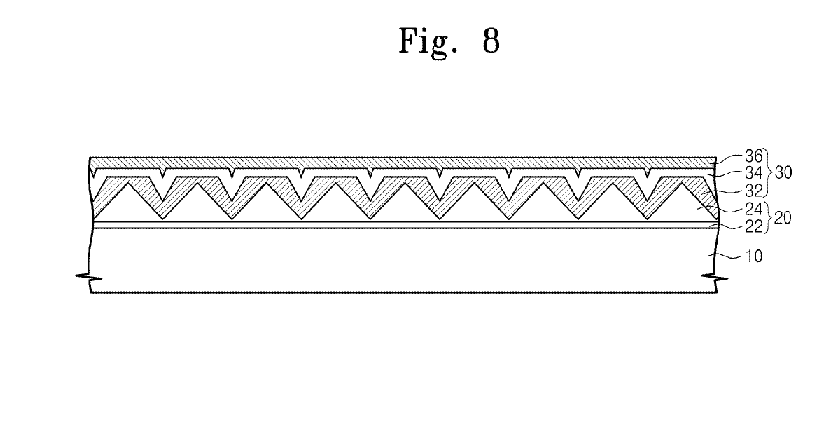

Referring to FIGS. 3 and 8, a third aluminum gallium nitride layer 36 is formed on the second aluminum gallium nitride layer 34. The gas supply unit 200 may provide about 120μ mol of trimethyl aluminum gas, about 120μ mol of trimethyl gallium gas, and about 5 liters of ammonia gas per minute into the reactor 100. The third aluminum gallium nitride layer 36 may include a lower amount of aluminum than the second aluminum gallium nitride layer 34. A content ratio of gallium to aluminum in the third aluminum gallium nitride layer 36 may be increased as the flow rate of the trimethyl gallium gas increases. The third aluminum gallium nitride layer 36 may be planarized by burying the valleys of the second aluminum gallium nitride layer 34. With respect to the crystal defects 40, the third aluminum gallium nitride layer 36 may have smaller crystal defects than the second aluminum gallium nitride layer 34 or the first aluminum gallium nitride layer 32.

Therefore, the method of fabricating an aluminum gallium nitride template according to an embodiment of the inventive concepts may minimize crystal defects.

Although not illustrated in the drawings, an nₜₕ aluminum gallium nitride layer, which is a fourth aluminum gallium nitride layer or more, may be formed on the third aluminum gallium nitride layer 36. Aluminum composition ratios of the fourth aluminum gallium nitride layer to the nₜₕ aluminum gallium nitride layer may be sequentially decreased or increased as heights of the layers are increased. Also, the crystal defects 40 may be decreased as a height from the fourth aluminum gallium nitride layer to the nₜₕ aluminum gallium nitride layer increases.

A method of fabricating an aluminum gallium nitride template according to an embodiment of the inventive concepts may include sequentially forming a flat aluminum nitride layer, an embossed aluminum nitride layer, and an aluminum gallium nitride layer on a substrate. The flat aluminum nitride layer may have crystal defects in a direction perpendicular to the substrate. The embossed aluminum nitride layer may be formed to have convex structures having the shape of a tetrahedron. The crystal defects may be bent and extend from an interface between the embossed aluminum nitride layer and the flat aluminum nitride layer in directions of edges of the convex structures having the shape of a tetrahedron. The aluminum gallium nitride layer may have smaller crystal defects than the embossed aluminum nitride layer. The crystal defects may be again bent and extend from an interface between the aluminum gallium nitride layer and the embossed aluminum nitride layer in the directions of the edges of the convex structures. The crystal defects may be removed in the aluminum gallium nitride layer.

Therefore, an aluminum gallium nitride template according to an embodiment of the inventive concepts and the fabrication method thereof may minimize or prevent crystal defects.

While this invention has been particularly shown and described with reference to preferred embodiments thereof, it will be understood by those skilled in the art that various changes in form and details may be made therein without departing from the spirit and scope of the invention as defined by the appended claims. The preferred embodiments should be considered in descriptive sense only and not for purposes of limitation. Therefore, the scope of the invention is defined not by the detailed description of the invention but by the appended claims, and all differences within the scope will be construed as being included in the present invention.

What is claimed is:

1. A method of fabricating an aluminum gallium nitride template, the method comprising:
forming an aluminum nitride (AlN) layer on a substrate;
forming a first aluminum gallium nitride (AlₓGa₁₋ₓN) layer on the aluminum nitride (AlN) layer;
forming a second aluminum gallium nitride (Al_{y}Ga_{1-y}N) layer on the first aluminum gallium nitride (AlₓGa₁₋ₓN) layer; and
forming a third aluminum gallium nitride (Al_{z}Ga_{1-z}N) layer on the second aluminum gallium nitride (Al_{y}Ga_{1-y}N) layer,
wherein the first aluminum gallium nitride (AlₓGa₁₋ₓN) layer, the second aluminum gallium nitride (Al_{y}Ga_{1-y}N) layer, and the third aluminum gallium nitride (Al_{z}Ga_{1-z}N) layer have crystal defects and a composition ratio of aluminum (where 1>x>y>z>0) that are gradually decreased as heights of the first aluminum gallium nitride (AlₓGa₁₋ₓN) layer, the second aluminum gallium nitride (Al_{y}Ga_{1-y}N) layer, and the third aluminum gallium nitride (Al_{z}Ga_{1-z}N) layer are increased.

2. The method of claim 1, wherein the forming the aluminum nitride (AlN) layer comprises:
forming a flat aluminum nitride (AlN) layer on the substrate; and
forming an embossed aluminum nitride (AlN) layer on the flat aluminum nitride layer.

3. The method of claim 2, wherein the embossed aluminum nitride (AlN) layer is formed of convex structures of a tetrahedral crystal structure.

4. The method of claim 3, wherein the crystal defects are bent at an interface between the embossed aluminum nitride (AlN) layer and the first aluminum gallium nitride (AlₓGa₁₋ₓN) layer in direction of edges of the convex structures.

5. The method of claim 2, wherein the embossed aluminum nitride (AlN) layer has smaller crystal defects than the flat aluminum nitride (AlN) layer.

6. The method of claim 2, wherein the first aluminum gallium nitride (AlₓGa₁₋ₓN) layer, the second aluminum gallium nitride (Al_{y}Ga_{1-y}N) layer, and the third aluminum gallium nitride (Al_{z}Ga_{1-z}N) layer are formed to be gradually flat on the embossed aluminum nitride (AlN) layer.

7. The method of claim 2, wherein the flat aluminum nitride (AlN) layer, the embossed aluminum nitride layer, the first aluminum gallium nitride (AlₓGa₁₋ₓN) layer, the second aluminum gallium nitride (Al_{y}Ga_{1-y}N) layer, and the third aluminum gallium nitride (Al_{z}Ga_{1-z}N) layer are formed by a metal organic chemical vapor deposition method.

8. The method of claim 7, wherein the flat aluminum nitride layer and the embossed aluminum nitride layer use trimethyl aluminum gas and ammonia gas as source gases of the metal organic chemical vapor deposition method.

9. The method of claim 8, wherein the flat aluminum nitride layer is formed from 120μ mol of the trimethyl aluminum gas and 5 liters of the ammonia gas.

10. The method of claim 9, wherein the embossed aluminum nitride layer is formed from 120μ mol of the trimethyl aluminum gas and 10 liters of the ammonia gas.

11. The method of claim 8, wherein the first aluminum gallium nitride (AlₓGa₁₋ₓN) layer, the second aluminum gallium nitride (Al_{y}Ga_{1-y}N) layer, and the third aluminum gallium nitride (Al_{z}Ga_{1-z}N) layer use the trimethyl aluminum gas, trimethyl gallium gas, and the ammonia gas as source gases of the metal organic chemical vapor deposition method.

12. The method of claim 11, wherein the first aluminum gallium nitride (AlₓGa₁₋ₓN) layer is formed from 120μ mol of the trimethyl aluminum gas, 60μ mol of the trimethyl gallium gas, and 5 liters of the ammonia gas.

13. The method of claim 11, wherein the second aluminum gallium nitride (Al_{y}Ga_{1-y}N) layer is formed from 120μ mol of the trimethyl aluminum gas, 90μ mol of the trimethyl gallium gas, and 5 liters of the ammonia gas.

14. The method of claim 11, wherein the third aluminum gallium nitride (Al_{z}Ga_{1-z}N) layer is formed from 120μ mol of the trimethyl aluminum gas, 120μ mol of the trimethyl gallium gas, and 5 liters of the ammonia gas.

15. An aluminum gallium nitride template comprising:
a substrate;
an aluminum nitride layer on the substrate; and
an aluminum gallium nitride layer covering the aluminum nitride layer and having smaller crystal defects than the aluminum nitride layer.

16. The aluminum gallium nitride template of claim 15, wherein the aluminum nitride layer comprises:
a flat aluminum nitride layer; and
an embossed aluminum nitride layer including convex structures protruding from the flat aluminum nitride layer.

17. The aluminum gallium nitride template of claim 16, wherein the convex structures of the embossed aluminum nitride layer have a tetrahedral crystal structure.

18. The aluminum gallium nitride template of claim 17, wherein the crystal defects are bent at an interface between the flat aluminum nitride layer and the embossed aluminum nitride layer in direction of edges of the convex structures.

19. The aluminum gallium nitride template of claim 18, wherein the crystal defects are again bent at an interface between the embossed aluminum nitride layer and the aluminum gallium nitride layer in direction of the edges of the convex structures.

20. The aluminum gallium nitride template of claim 15, wherein the aluminum gallium nitride layer comprises:
a first aluminum gallium nitride (AlₓGa₁₋ₓN) layer on the embossed aluminum nitride layer;
a second aluminum gallium nitride (Al_{y}Ga_{1-y}N) layer covering the first aluminum gallium nitride (AlₓGa₁₋ₓN) layer and having a higher composition ratio of aluminum than the first aluminum gallium nitride layer (AlₓGa₁₋ₓN); and
a third aluminum gallium nitride (Al_{z}Ga_{1-z}N) layer covering the second aluminum gallium nitride (Al_{y}Ga_{1-y}N) layer and having a higher composition ratio of aluminum than the second aluminum gallium nitride (Al_{y}Ga_{1-y}N) layer.
